(19) United States
(12) Patent Application Publication
(10) Pub. No.: US 2026/0211033 A1
(43) Pub. Date: Jul. 23, 2026

(54) CROSS-DIE HIGH-SPEED ACCESS AND TEST IMPLEMENTATION FOR IN-PACKAGE CHIPLET

(71) Applicant: Cisco Technology, Inc., San Jose, CA (US)

(72) Inventors: Chuanyun Fan, Fremont, CA (US); Keith M. Ring, San Francisco, CA (US)

(21) Appl. No.: 19/034,876

(22) Filed: Jan. 23, 2025

(51) Int. Cl. G01R 31/317

(52) U.S. Cl. CPC G01R 31/31715

(57) ABSTRACT

In one embodiment, an apparatus includes a main die, a plurality of chiplets including a first chiplet, and an extended Advanced Extensible Interface (AXI) network. The main die includes a first high speed input/output (IO) interface, at least a first main die die-to-die interface, and a main die AXI network. The first chiplet has at least a first chiplet die-to-die interface and a chiplet AXI network, the first chiplet including a first chiplet instance of high speed test logic. The extended AXI network includes the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface.

### TECHNICAL FIELD

The present disclosure relates to testing multi-die chip packages that include a main die and at least one chiplet.

### BACKGROUND

Semiconductor packages such as application specific integrated circuits (ASICs) often include a main die and multiple chiplets. Within a package, the integrity of connections between the main die and the multiple chiplets, as for example the interconnections therebetween, must be ensured if the package is to perform as expected.

Chiplet die edges are generally occupied by digital serializer/deserializer (serdes) interconnects, which serve as die-to-die interconnects, and die-to-die interface bumps. Therefore, limited space is available on chiplet die edges for general purpose inputs/outputs (GPIOs). As a result, the use of traditional scan automatic test pattern generation (ATPG) test payloads that transfer through GPIOs is generally not valid for use with respect to chiplets. Die-to-die interfaces of a chiplet are often not accessible in a package from automated test equipment (ATE).

While the use of serdes low speed analog input/output (IO) to scan payloads during transfer is used in some situations, the use of serdes low speed analog IO is a bottleneck with respect to further improvement of serdes speeds. Although serdes high speed analog IOs may be used to support low speed digital scan IOs in a scan test, such a solution is inefficient.

High access and test (HSAT) and scan through high speed IOs have been developed as scan test solutions, which are relatively efficient. However, such scan tests may be used substantially only for single dies, and may not be used with respect to packages which include a main die and multiple chiplets.

### BRIEF DESCRIPTION OF THE DRAWINGS

The disclosure will be readily understood by the following detailed description in conjunction with the accompanying drawings in which:

FIG. 1 is a block diagram representation of a multi-chip module or package.

FIG. 2 is a diagrammatic representation of a module or package that includes a main die with an in-chip Advanced Extensible Interface (AXI) network and chiplets that are in communication over a cross-die AXI network that is extended from the in-chip AXI network in accordance with an embodiment.

FIG. 3 is a diagrammatic representation of a module or package, e.g., package 100′ of FIG. 2, which includes instances of high speed IOs in accordance with an embodiment.

FIG. 4 is a block diagram representation of a chip package that includes a main die and a chiplet that are in communication using a cross-die AXI network in accordance with an embodiment.

FIG. 5 is a block diagram representation of a chip package, e.g., chip package 400 of FIG. 4, which includes high speed IO instances, e.g., scan through high speed IOs, in accordance with an embodiment.

FIG. 6 is a block diagram representation of a chip package that includes a plurality of chiplets and high speed IO instances in accordance with an embodiment.

FIG. 7 is a process flow diagram which illustrates a method of creating a chip package that includes a cross-die AXI network in accordance with an embodiment.

FIG. 8 is a process flow diagram which illustrates a method of implementing a scan test with respect to a chip package that includes a cross-die AXI network in accordance with an embodiment,

FIG. 9 is a hardware block diagram of a networking/computing device/apparatus/appliance/endpoint that may be cooled using techniques described with respect to FIGS. 1-8.

### DETAILED DESCRIPTION

### Overview

Techniques are presented herein that enable high speed scan tests to be run on a chip package that includes a main die and at least one chiplet. Chiplet scan access is provided by extending an in-chip Advanced Extensible Interface (AXI) network of the main die to be a cross-die AXI network with an AXI bus that passes through a die-to-die interface of the main die to a die-to-die interface of the chiplet. A high speed input/output (IO) port of the main die may be exposed externally with respect to the chip package, and a scan test pattern may be obtained through the high speed IO port. Such a high speed IO port may be a peripheral component interconnect express (PCIe) or PCIe interface, and may be used to provide scan test access to the chiplet.

According to one aspect, an apparatus includes a main die, a plurality of chiplets including a first chiplet, and an extended Advanced Extensible Interface (AXI) network. The main die includes a first high speed input/output (IO) interface, at least a first main die die-to-die interface, and a main die AXI network. The first chiplet has at least a first chiplet die-to-die interface and a chiplet AXI network, the first chiplet including a first chiplet instance of high speed test logic. The extended AXI network includes the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface.

In accordance with another embodiment, a system includes a chip package and an automated test equipment (ATE). The chip package includes a main die and a plurality of chiplets including a first chiplet, and an extended AXI network. The main die includes a first high speed IO interface that is accessible externally to the chip package, at least a first main die die-to-die interface, and a main die AXI network. The first chiplet has at least a first chiplet die-to-die interface and a chiplet AXI network, the first chiplet including a first chiplet instance of high speed test logic. The extended AXI network includes the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface. The ATE is external to the chip package and configured to provide a scan test pattern to the first high speed IO interface.

In accordance with still another embodiment, a method includes initializing a first main die die-to-die interface on a main die of a package, wherein the main die includes a first high speed test logic instance and a high speed IO interface. The method also includes initializing a first chiplet die-to-die interface on a first chiplet of the package, wherein the first chiplet includes a second high speed test logic instance, the first main die die-to-die interface and the first chiplet die-to-die interface being in communication on a physical AXI bus of a cross-die AXI network between the first main die and the first chiplet. A scan test is obtained on the high speed IO interface, the scan test pattern being associated with a high speed test, wherein the scan test pattern is obtained from an ATE. The scan test pattern is provided to the first chiplet on the physical AXI bus, and the high speed test is performed the scan test pattern with respect to the first chiplet die-to-die interface.

### Example Embodiments

Multi-chip modules, multi-die devices, and chip packages, my generally include a main die and one or more chiplets, e.g., integrated circuits. The main die is communicably coupled to, or otherwise interconnected with, each of the chiplets. In general, a main die may be arranged to effectively interconnect chiplets within a module or package. A main die may have at least one peripheral component interconnect express (PCIe) interface that is effectively exposed, e.g., externally exposed, with respect to a module or package, whereas a chiplet may not have a PCIe that is effectively exposed with respect to the module or package.

A chiplet is an integrated circuit that has a particular functionality, and is designed to cooperate with other chiplets to form relatively complex chips or multi-chip modules such as system-on-chips (SoCs). Chiplets within multi-chip modules may be formed as silicon chips, and may be selected, arranged, and/or assembled based on a desired chip functionality. In other words, a main die and chiplets may be packaged together, as for example on a substrate, to provide a desired overall functionality. A multi-chip module may be, but is not limited to being, a processor, a signal processor, a sensor, and the like.

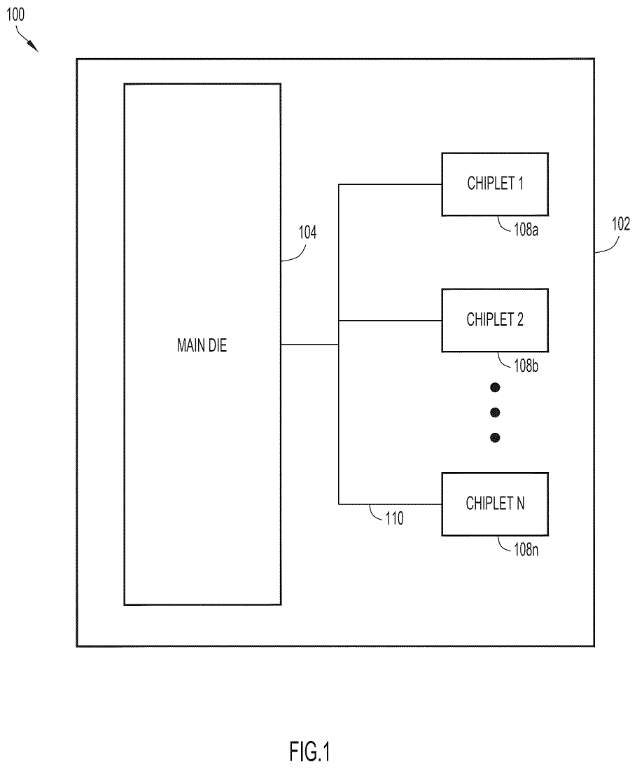

Referring initially to FIG. 1, a multi-chip module or package will be described. A module or package 100 includes a main die 104 and one or more chiplets 108a-n mounted, or otherwise substantially attached to, a substrate 102. Main die 104 is communicably coupled to chiplets 108a-n through an interconnect network 110. As shown, interconnect network 110 communicably connects main die 104 to a first chiplet 108a, a second chiplet 108b, and an Nth chiplet 108n. Both main die 104 and chiplets 108a-n may function as a transmitter and a receiver.

Data may generally be transferred on interconnect network 110 between main die 104 and chiplets 108a-n. As will be discussed below, relatively high speed die-to-die interconnects may be associated with interconnect network 110, and may facilitate a relatively high-speed transfer of data between main die 104 and chiplets 108a-n. Such die-to-die interconnects may accommodate relatively high-speed transfer of data without utilizing a relatively high number of die-to-die interconnects. It should be understood that the number of chiplets 108a-n included in module or package 100 may vary widely, and may include fewer than or more than the number of chiplets 108a-n shown.

To test the integrity, as for example structural integrity, of module or package 100, scan tests may be run using automated test equipment (ATE). Test patterns may be generated, and the expected response to the test patterns may be stored in ATE. Module or package 100 may be tested using the ATE, which effectively provides a pattern to module or package 100, and compares results of a scan test run using the pattern with the expected response to determine a status, as for example a pass or fail status.

Running scan tests on chiplets is generally not efficient for relatively high speeds, and scan tests. Further, conventionally, a high speed scan test, as for example a test that involves a scan through a high speed IO, or a scan test that is run through high speed IO protocols may not be run on module or package 100 because module or package 100 includes multiple dies, e.g., main die 104 and chiplets 108a-n.

When a main die of a module or package such as main die 104 includes an Advanced Extensible Interface (AXI) network, extending the AXI network of the main die to a cross-die AXI network enables a PCIe of a chiplet of the module or package to be used for chiplet test access. Typically, a PCIe of a chiplet such as one of chiplets 108a-n is not exposed at a module or package level. In other words, during a scan test run on a module or a package, substantially only the PCIe of the main die is accessible, e.g., to a host such as ATE. Extending an in-chip AXI network of a main die to be a cross-die AXI network in which an AXI physical bus passes through a die-to-die interface to provide in-module or in-package chiplet scan access to enable a scan test to be run. In one embodiment, a scan test may be run using a PCIe of a main die, or any suitable relatively high speed input/output (IO) interfaces, e.g., USB, to obtain testing, debugging, and/or monitoring data associated with a multi-die module or package substantially without utilizing multiple IO interfaces.

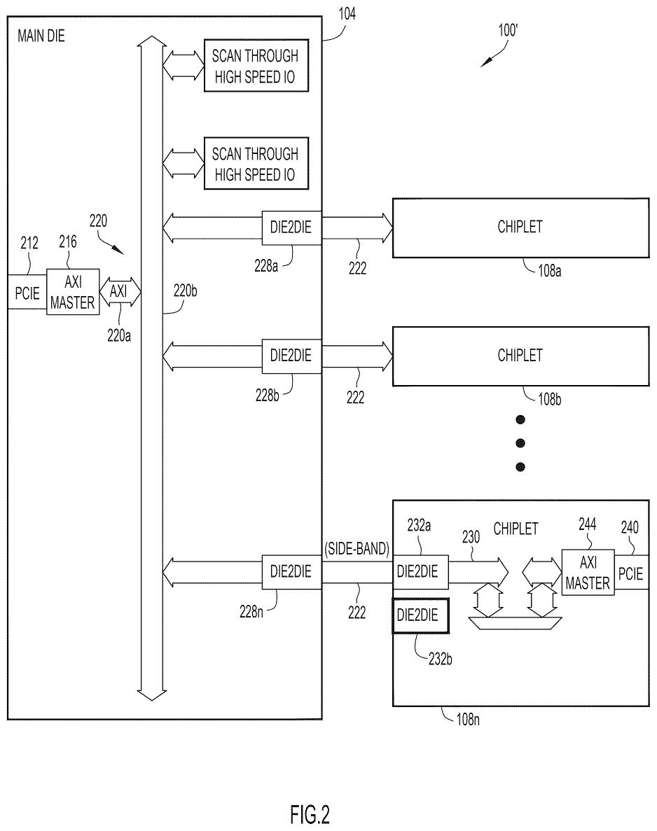

FIG. 2 is a diagrammatic representation of a module or package that includes a main die with an in-chip AXI network and chiplets that are in communication over a cross-die AXI network that is extended from the in-chip AXI network in accordance with an embodiment. A module or package 100′ includes main die 104 and chiplets 108a-n. Main die 104 includes a PCIe 212 that may effectively be externally exposed with respect to package 100′. PCIe 212 is generally a high speed IO and is associated with an AXI master 216 that is communicably coupled to an in-chip AXI network 220 that includes AXI connection 220a and an AXI bus 220b. AXI master 216 may send or otherwise provide write transaction data to in-chip AXI network 220 that is obtained from PCIe 212 which may be a PCIe controller. In one embodiment, AXI master 216 is effectively the initiator of transactions on in-chip AXI network 220, and may effectively be part of the functionality of PCIe 212. PCIe 212 may include a PCIe controller that converts a PCIE protocol from a PCIe IO to an in-chip PCIe protocol and to initiate the in-chip PCIe protocol from AXI master 216.

AXI network 220 is extended to a cross-die AXI network 222 through die-to-die interfaces 228a-n to chiplets 108a-n. For example, cross-die AXI network 222 is extended through die-to-die interface 228a to chiplet 108a, through die-to-die interface 228b to chiplet 108b, and extended through die-to-die interface 228n to chiplet 108n. AXI network 220 and cross-die AXI network 222 maintain AXI protocol standards. Together, AXI network 220 and cross-die AXI network 222 effectively form an extended main-die AXI network.

Chiplet 108n includes a PCIe 240, which may be or otherwise include a PCIe controller, and an associated AXI master 244. AXI master 244 may be included in the PCIe controller associated with PCIe 240. PCIe 240 is not externally accessible with respect to package 100', e.g., PCIe 240 is not exposed to an external host. Within package 100', PCIe 212 is generally the only PCIe that is externally accessible or exposed.

Chiplet 108n includes a first die-to-die interface 232a, a second die-to-die interface 232b, and an AXI network 230. Cross-die AXI network 222 includes physical AXI buses that pass through die-to-die interfaces 228a-n and die-to-die interface 232a. It should be appreciated that chiplet 108a and chiplet 108b may also include die-to-die interfaces (not shown) and AXI networks (not shown). First die-to-die interface 232a is in communication with cross-die AXI network 222, which maintains AXI protocol standards, such that data may be transferred through die-to-die interface 232a. In the embodiment as shown, die-to-die interface 232b is effectively unused by cross-die AXI network 222.

A portion of cross-die AXI network 222 between die-to-die interface 228n and die-to-die interface 232a may effectively be a sideband that enables main die 104 and chiplet 108n to communicate. As will be appreciated by those in the art, a sideband effectively supports communications that are not sent inband on a primary interface. In one embodiment, the portion of cross-die AXI network 222 between die-to-die interface 228n and die-to-die interface 232a that forms a sideband may be a substantially dedicated channel that is arranged to support data transfer associated with scan testing.

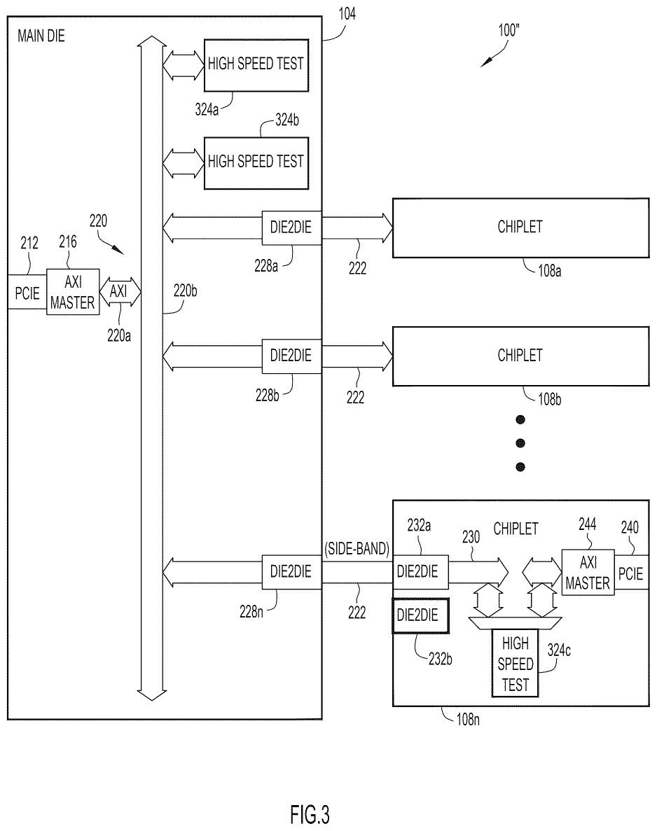

FIG. 3 is a diagrammatic representation of a module or package, e.g., package 100′ of FIG. 2, which includes instances of high speed IOs in accordance with an embodiment. During a high speed scan test, PCIe 212 may obtain data such as a high speed access packet from a host, and provide the data to AXI network 220 and cross-die AXI network 220. An instance of a high speed test logic 324a and an instance of high speed test logic 324b are effectively connected to AXI network 220 and cross-die AXI network 222. An instance of high speed test logic 324c is effectively connected to chiplet AXI network 230. High speed test logic 324b contains an AXI slave interface and may effectively be connected as a slave to AXI network 220. Either AXI master 244 or AXI master 216 may be selected as an overall AXI master to communicate with the AXI slave inside instance of high speed test logic 324b. As will be appreciated by those skilled in the art, to perform or to enable a scan test for a package 100″, test logic is inserted in package 100″, as for example by providing high speed test logic 324 a and high speed test logic 324b to main die 104, and by providing high speed test logic 324c to chiplet 108n. A scan insertion process allows a high speed scan test such as HSAT to be run on package 100″. That is, high speed test logic 324a-c enables a high speed scan test to be run with respect to package 100 when a scan test pattern is provided to PCIe 212. It should be appreciated that high speed test logic 324a-c may include, but is not limited to including, hardware and/or software logic.

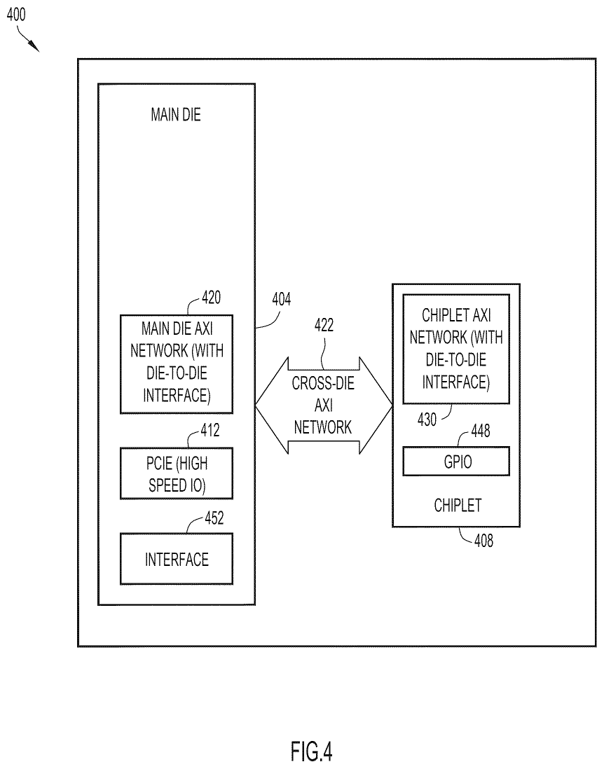

With reference to FIG. 4, communications between a main die and a chiplet using a cross-die AXI network within a multi-die module or package will be described in accordance with an embodiment. A module or package 400 includes a main die 404 and a chiplet 408. Main die 404 and chiplet 408 are in communication via a cross-die AXI network 422. Cross-die AXI network 422 may be an extension of a main die AXI network 420, and is in communication with a chiplet AXI network 430. Main die AXI network 420 and cross-die AXI network 422 effectively form an extended main die AXI network.

Main die includes a PCIe 412 or, more generally, a high speed IO port in addition to main die AXI network 420. Further, main die 404 includes an interface 452 that may be used to control, or to otherwise access, chiplet 408 through main die AXI network 420 and cross-die AXI network 422. Chiplet 408 includes chiplet AXI network 420 and a GPIO 448. As mentioned above, an extended AXI network that includes main die AXI network 420 and cross-die AXI network 422 includes an AXI physical bus that passes through a die-to-die interface of main die 404 to a die-to-die interface of chiplet 408.

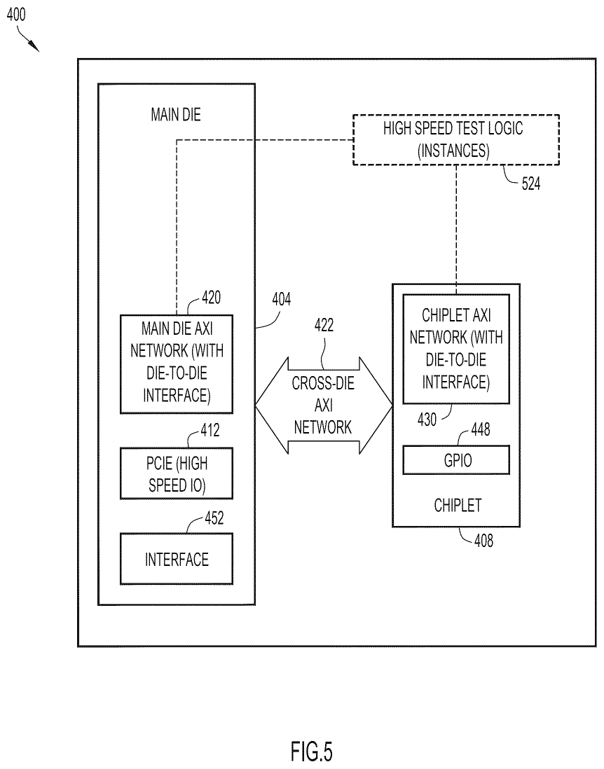

As shown in FIG. 5, high speed test logic 524, or instances of high speed test logic 524, are effectively coupled or otherwise provided to main die AXI network 420 and chiplet AXI network 420. That is, a high speed test logic 524 may effectively be hooked up to both an extended main die AXI that includes main die AXI network 420 and cross-die AXI network 422, and chiplet AXI network 430. Interface 452 may include a multiplexer (MUX) that is arranged to effectively select chiplet AXI network 430 for a scan test, while GPIO 448 provides a selection signal that is tied to a particular constant level.

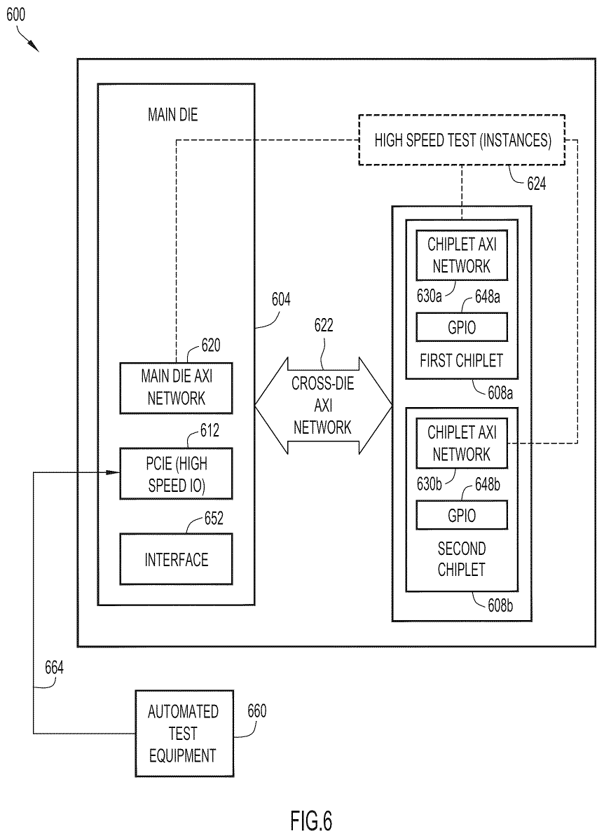

It should be understood that a MUX of interface 452 generally selects an appropriate chiplet AXI network such as chiplet AXI network 430 when there is more than one chiplet 408 in package 400. With reference to FIG. 6, communications associated with a multi-die module or package that includes a plurality of chiplets will be described in accordance with an embodiment. A module or package 600 includes a main die 604 and at least a first chiplet 608a and a second chiplet 608b. Main die 604 includes a main die AXI network 620 that is effectively extended to include a cross-die AXI network 622. Main die 604 also includes a PCIe 612 and an interface 652 that may include a MUX. An instance of high speed test logic 624 is effectively coupled to main die AXI network 620.

First chiplet 608a includes a first chiplet AXI network 630a and a GPIO 648a, and second chiplet 608b includes a second chiplet AXI network 630b and a GPIO 648b. Instances of high speed test logic 624 are effectively coupled to chiplet AXI network 630a and chiplet AXI network 630b. When a scan test is initiated, as for example when PCIe 612 obtains a scan test pattern 664 from a host such as an ATE 660, interface 652 may select either first chiplet AXI network 630a or second chiplet AXI network 630b for a scan test. In other words, interface 652 may be used by main die 604 to control or to otherwise access first chiplet 608a and second chiplet 608b.

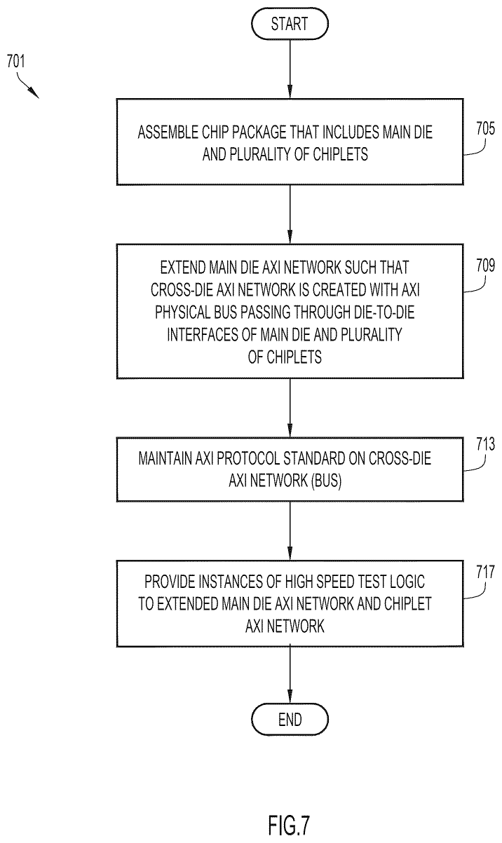

FIG. 7 is a process flow diagram which illustrates a method of creating a chip package that includes a cross-die AXI network, or an extended main die AXI network, in accordance with an embodiment. A method 701 of creating a chip package begins at a step 705 in which a chip package is assembled to include a main die and a plurality of chiplets. The main die and the plurality of chiplets may be assembled on a substrate, or a printed circuit board (PCB), to create the chip package. In one embodiment, a PCIe interface or other high speed IO interface of the main die is externally exposed with respect to the chip package, while a PCIe interface or other high speed interface of each chiplet is not externally exposed with respect to the chip package. The main die has an internal main die AXI network, and each chiplet of the plurality of chiplets has an internal chiplet AXI network.

From step 705, process flow proceeds to a step 709 in which the main die AXI network is extended such that a cross-die network is created between the main die and the plurality of chiplets in a step 709. Extending the main die AXI network such that a cross-die AXI network is created between the main die and each chiplet of a plurality of chiplets includes enabling a physical AXI bus to pass through one or more die-to-die interfaces of the main die to die-to-die interfaces of the plurality of chiplets.

In one embodiment, the cross-die AXI network or connection between a die-to-die interface of a main die and a die-to-die interface of a first chiplet of a plurality of chiplets may be a sideband. As such, communications on the cross-die AXI network or connection may effectively be sent on a sideband, and not inband on a primary interface.

Once the main die AXI network is extended, an AXI protocol standard may be maintained with respect to the cross-die AXI network in a step 713. For example, the cross-die AXI network may comply with AXI protocol standards as defined in the Advanced Microcontroller Bus Architecture (AMBA) specification. In a step 717, a scan insertion process may effectively couple instances of high speed test logic, as for example instances of HSAT logic, to an extended main die AXI network and to chiplet AXI networks of the plurality of chiplets. Upon providing high speed test logic, the method of creating a chip package is completed.

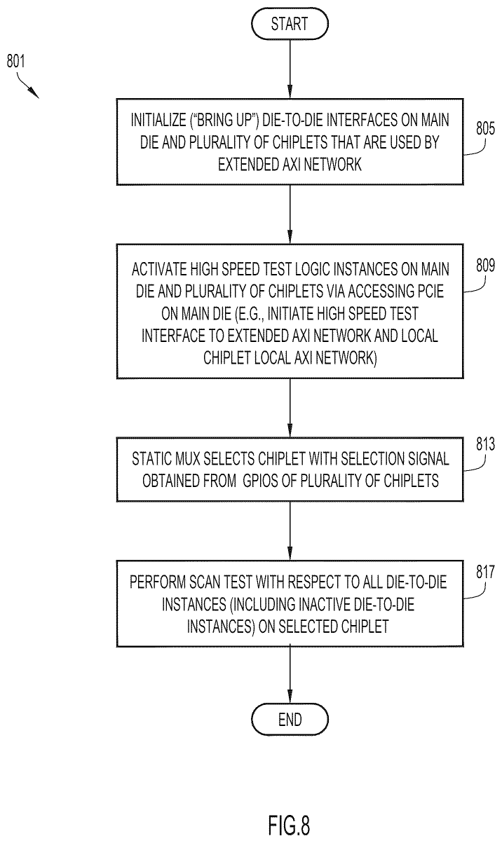

Referring next to FIG. 8, a method of implementing a high speed scan test with respect to a chip package that includes a cross-die AXI network will be described in accordance with an embodiment. A method 801 of implementing a high speed scan test begins at a step 805 in which die-to-die interfaces on a main die and die-to-die interfaces on a plurality of chiplets in a chip package which are used by an extended AXI network are initialized.

In a step 809, high speed test logic instances on the main die and plurality of chiplets are activated via accessing a PCIe of the main die. That is, the high speed test logic instances in communication with the extended AXI network and the chiplet AXI networks are initiated. A host such as an ATE may provide a scan test pattern to the PCIe of the main die that effectively causes the high speed test logic instances to be activated. In one embodiment, the scan test pattern may be an HSAT pattern, and the high speed test logic instances may be HSAT instances.

After the high speed test logic instances on the main die and on the plurality of chiplets is activated, a static MUX of an interface on the main die effectively selects a chiplet from the plurality of chiplets to test in a step 813. The selection may be made based on a selection signal obtained from one or more signals obtained from one or more GPIOs of the plurality of chiplets. That is, the MUX of the interface utilizes the one or more selection signal to determine which chiplet of the plurality of chiplets to subject to the scan test.

In a step 817, a scan test is performed with respect to all die-to-die instances on the selected chiplet. Performing the scan test may include, but is not limited to including, providing a scan test pattern obtained on the PCIe of the main die to the extended AXI network and the chiplet AXI network of the selected chiplet. During the scan test, the high speed test logic instance of the selected chiplet may effectively function as an AXI slave while the main die is an AXI master. After the scan test is performed, the method of implementing a high speed scan test is completed.

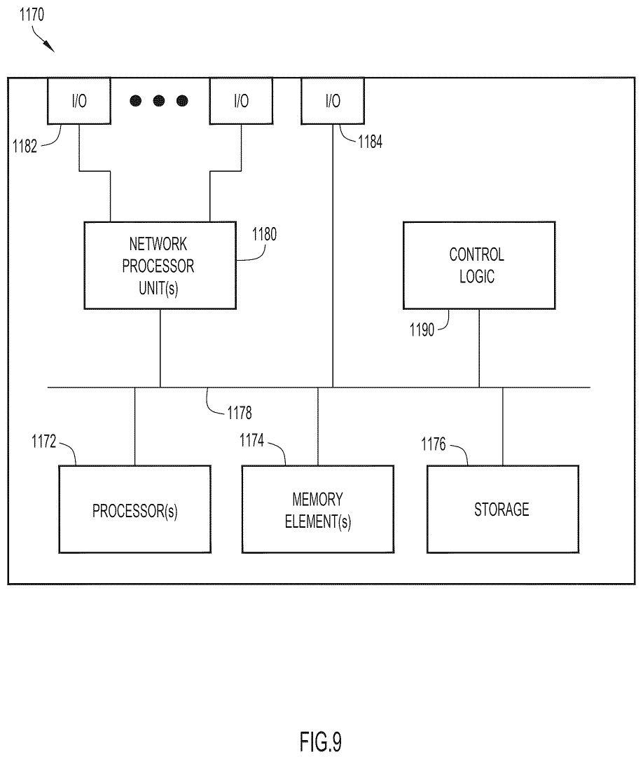

FIG. 9 is a hardware block diagram of a networking/computing device/apparatus/appliance/endpoint that may be cooled using the techniques described with respect to FIGS. 1-8, e.g., the networking/computing device/apparatus/appliance/endpoint may be embodied as, or include, the chip package and techniques described above. It should be appreciated that FIG. 9 provides only an illustration of one example embodiment and does not imply any limitations with regard to the environments in which different example embodiments may be implemented. Many modifications to the depicted environment may be made.

In at least one embodiment, the computing device 1170 may be any apparatus that may include one or more processor(s) 1172, one or more memory element(s) 1174, storage 1176, a bus 1178, one or more network processor unit(s) 1180 interconnected with one or more network input/output (I/O) interface(s) 1182, one or more I/O interface(s) 1184, and control logic 1190. In various embodiments, instructions associated with logic for computing device 1170 may overlap in any manner and are not limited to the specific allocation of instructions and/or operations described herein.

In at least one embodiment, processor(s) 1172 is/are at least one hardware processor configured to execute various tasks, operations and/or functions for device 1170 as described herein according to software and/or instructions configured for device 1170. Processor(s) 1172 (e.g., a hardware processor) may execute any type of instructions associated with data to achieve the operations detailed herein. In one example, processor(s) 1172 may transform an element or an article (e.g., data, information) from one state or thing to another state or thing. Any of potential processing elements, microprocessors, digital signal processor, baseband signal processor, modem, PHY, controllers, systems, managers, logic, and/or machines described herein may be construed as being encompassed within the broad term ‘processor’.

In at least one embodiment, one or more memory element(s) 1174 and/or storage 1176 is/are configured to store data, information, software, and/or instructions associated with device 1170, and/or logic configured for memory element(s) 1174 and/or storage 1176. For example, any logic described herein (e.g., control logic 1190) may, in various embodiments, be stored for device 1170 using any combination of memory element(s) 1174 and/or storage 1176. Note that in some embodiments, storage 1176 may be consolidated with one or more memory elements 1174 (or vice versa), or may overlap/exist in any other suitable manner. In one or more example embodiments, process data is also stored in the one or more memory elements 1174 for later evaluation and/or process optimization.

In at least one embodiment, bus 1178 may be configured as an interface that enables one or more elements of device 1170 to communicate in order to exchange information and/or data. Bus 1178 may be implemented with any architecture designed for passing control, data and/or information between processors, memory elements/storage, peripheral devices, and/or any other hardware and/or software components that may be configured for device 1170. In at least one embodiment, bus 1178 may be implemented as a fast kernel-hosted interconnect, potentially using shared memory between processes (e.g., logic), which may enable efficient communication paths between the processes.

In various embodiments, network processor unit(s) 1180 may enable communication between computing device 1170 and other systems, entities, etc., via network I/O interface(s) 1182 (wired and/or wireless) to facilitate operations discussed for various embodiments described herein. In various embodiments, network processor unit(s) 1180 may be configured as a combination of hardware and/or software, such as one or more Ethernet driver(s) and/or controller(s) or interface cards, Fibre Channel (e.g., optical) driver(s) and/or controller(s), wireless receivers/transmitters/transceivers, baseband processor(s)/modem(s), and/or other similar network interface driver(s) and/or controller(s) now known or hereafter developed to enable communications between computing device 1170 and other systems, entities, etc. to facilitate operations for various embodiments described herein. In various embodiments, network I/O interface(s) 1182 may be configured as one or more Ethernet port(s), Fibre Channel ports, any other I/O port(s), and/or antenna(s)/antenna array(s) now known or hereafter developed. Thus, the network processor unit(s) 1180 and/or network I/O interface(s) 1182 may include suitable interfaces for receiving, transmitting, and/or otherwise communicating data and/or information in a network environment.

I/O interface(s) 1184 allow for input and output of data and/or information with other entities that may be connected to device 1170. For example, I/O interface(s) 1184 may provide a connection to external devices such as a keyboard, keypad, a touch screen, and/or any other suitable input device now known or hereafter developed. In some instances, external devices may also include portable computer readable (non-transitory) storage media such as database systems, thumb drives, portable optical or magnetic disks, and memory cards.

In various embodiments, control logic 1190 may include instructions that, when executed, cause processor(s) 1172 to perform operations, which may include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic 1190) may be identified based upon the application(s) for which they are implemented in a specific embodiment. However, it should be appreciated that any particular program nomenclature herein is used merely for convenience, and thus the embodiments herein should not be limited to use(s) solely described in any specific application(s) identified and/or implied by such nomenclature.

In the event the device 1170 is an endpoint (such as telephone, mobile phone, desk phone, conference endpoint, etc.), then the device 1170 may further include a sound processor, a speaker that plays out audio, and a microphone that detects audio. A sound processor may be a sound accelerator card or other similar audio processor that may be based on one or more ASICs and associated digital-to-analog and analog-to-digital circuitry to convert signals between the analog domain and digital domain. In some forms, the sound processor may include one or more digital signal processors (DSPs) and be configured to perform some or all of the operations of the techniques presented herein. The device 1170 may further include a video camera.

In some aspects, the techniques described herein relate to an apparatus including: a main die, the main die including a first high speed input/output (IO) interface, at least a first main die die-to-die interface, and a main die Advanced Extensible Interface (AXI) network; a plurality of chiplets including a first chiplet, the first chiplet having at least a first chiplet die-to-die interface and a chiplet AXI network, the first chiplet including a first chiplet instance of high speed test logic; and an extended AXI network, the extended AXI network including the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface.

In some aspects, the techniques described herein relate to an apparatus wherein the first high speed IO interface is a peripheral component interconnect express (PCIe) interface.

In some aspects, the techniques described herein relate to an apparatus further including: at least a first main die instance of the high speed test logic, the at least first main die instance of the high speed test logic being coupled to the extended AXI network.

In some aspects, the techniques described herein relate to an apparatus wherein the extended AXI network includes a cross-die AXI network arranged between the main die and the plurality of chiplets.

In some aspects, the techniques described herein relate to an apparatus wherein the physical bus is a sideband.

In some aspects, the techniques described herein relate to an apparatus wherein the first chiplet instance of the high speed test logic is a first chiplet instance of a high speed access and test (HSAT) and wherein the first main die instance of the high speed test logic is the HSAT.

In some aspects, the techniques described herein relate to an apparatus wherein the main die includes an interface, the interface being configured to cause the main die to select the first chiplet for a high speed scan test when a scan test pattern is obtained by the PCIe.

In some aspects, the techniques described herein relate to a system including: a chip package, the chip package including a main die and a plurality of chiplets including a first chiplet, and an extended Advanced Extensible Interface (AXI) network, the main die including a first high speed input/output (IO) interface that is accessible externally to the chip package, at least a first main die die-to-die interface, and a main die AXI network, the first chiplet having at least a first chiplet die-to-die interface and a chiplet AXI network, the first chiplet including a first chiplet instance of high speed test logic, the extended AXI network including the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface; and an automated test equipment (ATE), the ATE being external to the chip package and configured to provide a scan test pattern to the first high speed IO interface.

In some aspects, the techniques described herein relate to a system wherein the first high speed IO interface is a peripheral component interconnect express (PCIe) interface.

In some aspects, the techniques described herein relate to a system further including: at least a first main die instance of the high speed test logic, the at least first main die instance of the high speed test logic being coupled to the extended AXI network.

In some aspects, the techniques described herein relate to a system wherein the extended AXI network includes a cross-die AXI network arranged between the main die and the plurality of chiplets.

In some aspects, the techniques described herein relate to a system wherein the physical bus is a sideband, and wherein the scan test pattern is provided on the sideband.

In some aspects, the techniques described herein relate to a system wherein the first chiplet instance of the high speed test logic is a first chiplet instance of a high speed access and test (HSAT) the first main die instance of the high speed test logic is the HSAT, and wherein the scan test pattern is an HSAT scan test pattern.

In some aspects, the techniques described herein relate to a system wherein the main die includes an interface, the interface being configured to cause the main die to select the first chiplet for a high speed scan test when a scan test pattern is obtained from the ATE by the PCIe.

In some aspects, the techniques described herein relate to a method including: initializing a first main die die-to-die interface on a main die of a package, wherein the main die includes a first high speed test logic instance and a high speed input/output (IO) interface; initializing a first chiplet die-to-die interface on a first chiplet of the package, wherein the first chiplet includes a second high speed test logic instance, the first main die die-to-die interface and the first chiplet die-to-die interface being in communication on a physical Advanced Extensible Interface (AXI) bus of a cross-die AXI network between the first main die and the first chiplet;
obtaining a scan test pattern on the high speed IO interface, the scan test pattern being associated with a high speed test, wherein the scan test pattern is obtained from an automated test equipment (ATE); providing the scan test pattern to the first chiplet on the physical AXI bus; and performing the high speed test using the scan test pattern with respect to the first chiplet die-to-die interface.

In some aspects, the techniques described herein relate to a method wherein the high speed IO interface is a peripheral component interconnect express (PCIe) interface, and wherein the high speed test is a high speed access and test (HSAT).

In some aspects, the techniques described herein relate to a method wherein the first chiplet includes a second chiplet die-to-die interface, the first chiplet die-to-die interface being active, the second chiplet die-to-die interface being inactive, the method further including:
performing the high speed test using the scan test pattern with respect to the second chiplet die-to-die interface.

In some aspects, the techniques described herein relate to a method wherein the main die includes an interface, the method further including: selecting the first chiplet from a plurality of chiplets for the high speed test using the interface.

In some aspects, the techniques described herein relate to a method wherein the first chiplet includes a general purpose IO (GPIO), the method further including: providing a selection signal from the GPIO to the interface, wherein selecting the first chiplet from the plurality of chiplets includes utilizing the selection signal.

In some aspects, the techniques described herein relate to a method wherein the first main die includes a main die AXI network and the first chiplet includes a first chiplet AXI network, and wherein the cross-die AXI network and the main die AXI network form an extended main die AXI network.

Although only a few embodiments have been described in this disclosure, it should be understood that the disclosure may be embodied in many other specific forms without departing from the spirit or the scope of the present disclosure. By way of example, while a PCIe of a main die that is part of a chip package has been described as being suitable for obtaining a scan test pattern from a host, other high speed IOs of the main die may be used for obtaining a scan test pattern. In one embodiment, a USB port may obtain a scan test pattern.

In various embodiments, entities as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which may be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, the storage 1176 and/or memory elements(s) 1174 may store data, software, code, instructions (e.g., processor instructions), logic, parameters, combinations thereof, and/or the like used for operations described herein. This includes the storage 1176 and/or memory elements(s) 1174 being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

### Variations and Implementations

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi 6®), IEEE 802.16 (e.g., Worldwide Interoperability for Microwave Access (WiMAX)), Radio-Frequency Identification (RFID), Near Field Communication (NFC), Bluetooth™, mm. wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

In various example implementations, any entity or apparatus for various embodiments described herein can encompass network elements (which can include virtualized network elements, functions, etc.) such as, for example, network appliances, forwarders, routers, servers, switches, gateways, bridges, loadbalancers, firewalls, processors, modules, radio receivers/transmitters, or any other suitable device, component, element, or object operable to exchange information that facilitates or otherwise helps to facilitate various operations in a network environment as described for various embodiments herein. Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4(IPv4 ) and/or IP version 6(IPv6 ) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value.

Similarly, when a given feature is described as being “substantially parallel” to another feature, “generally perpendicular” to another feature, and so forth, this is intended to convey that the given feature is within +/−5%, within +/−4%, within +/−3%, within +/-2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a main die, the main die including a first high speed input/output (IO) interface, at least a first main die die-to-die interface, and a main die Advanced Extensible Interface (AXI) network;
a plurality of chiplets including a first chiplet, the first chiplet having at least a first chiplet die-to-die interface and a chiplet AXI network, the first chiplet including a first chiplet instance of high speed test logic; and
an extended AXI network, the extended AXI network including the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface.

2. The apparatus of claim 1 wherein the first high speed IO interface is a peripheral component interconnect express (PCIe) interface.

3. The apparatus of claim 2 further including:
at least a first main die instance of the high speed test logic, the at least first main die instance of the high speed test logic being coupled to the extended AXI network.

4. The apparatus of claim 3 wherein the extended AXI network includes a cross-die AXI network arranged between the main die and the plurality of chiplets.

5. The apparatus of claim 3 wherein the physical bus is a sideband.

6. The apparatus of claim 3 wherein the first chiplet instance of the high speed test logic is a first chiplet instance of a high speed access and test (HSAT) and wherein the first main die instance of the high speed test logic is the HSAT.

7. The apparatus of claim 2 wherein the main die includes an interface, the interface being configured to cause the main die to select the first chiplet for a high speed scan test when a scan test pattern is obtained by the PCIe.

8. A system comprising:
a chip package, the chip package including a main die and a plurality of chiplets including a first chiplet, and an extended Advanced Extensible Interface (AXI) network,
the main die including a first high speed input/output (IO) interface that is accessible externally to the chip package, at least a first main die die-to-die interface, and a main die AXI network,
the first chiplet having at least a first chiplet die-to-die interface and a chiplet AXI network, the first chiplet including a first chiplet instance of high speed test logic, the extended AXI network including the main die AXI network, wherein the extended AXI network includes a physical bus that is arranged between the first main die die-to-die interface and the first chiplet die-to-die interface, and wherein the first chiplet instance of the high speed test logic is accessible through the first high speed IO interface; and
an automated test equipment (ATE), the ATE being external to the chip package and configured to provide a scan test pattern to the first high speed IO interface.

9. The system of claim 8 wherein the first high speed IO interface is a peripheral component interconnect express (PCIe) interface.

10. The system of claim 9 further including:
at least a first main die instance of the high speed test logic, the at least first main die instance of the high speed test logic being coupled to the extended AXI network.

11. The system of claim 10 wherein the extended AXI network includes a cross-die AXI network arranged between the main die and the plurality of chiplets.

12. The system of claim 10 wherein the physical bus is a sideband, and wherein the scan test pattern is provided on the sideband.

13. The system of claim 10 wherein the first chiplet instance of the high speed test logic is a first chiplet instance of a high speed access and test (HSAT) the first main die instance of the high speed test logic is the HSAT, and wherein the scan test pattern is an HSAT scan test pattern.

14. The system of claim 9 wherein the main die includes an interface, the interface being configured to cause the main die to select the first chiplet for a high speed scan test when a scan test pattern is obtained from the ATE by the PCIe.

15. A method comprising:
initializing a first main die die-to-die interface on a main die of a package, wherein the main die includes a first high speed test logic instance and a high speed input/output (IO) interface;
initializing a first chiplet die-to-die interface on a first chiplet of the package, wherein the first chiplet includes a second high speed test logic instance, the first main die die-to-die interface and the first chiplet die-to-die interface being in communication on a physical Advanced Extensible Interface (AXI) bus of a cross-die AXI network between the first main die and the first chiplet;
obtaining a scan test pattern on the high speed IO interface, the scan test pattern being associated with a high speed test, wherein the scan test pattern is obtained from an automated test equipment (ATE);
providing the scan test pattern to the first chiplet on the physical AXI bus; and
performing the high speed test using the scan test pattern with respect to the first chiplet die-to-die interface.

16. The method of claim 15 wherein the high speed IO interface is a peripheral component interconnect express (PCIe) interface, and wherein the high speed test is a high speed access and test (HSAT).

17. The method of claim 16 wherein the first chiplet includes a second chiplet die-to-die interface, the first chiplet die-to-die interface being active, the second chiplet die-to-die interface being inactive, the method further including:
performing the high speed test using the scan test pattern with respect to the second chiplet die-to-die interface.

18. The method of claim 16 wherein the main die includes an interface, the method further including:
selecting the first chiplet from a plurality of chiplets for the high speed test using the interface.

19. The method of claim 18 wherein the first chiplet includes a general purpose IO (GPIO), the method further including:
providing a selection signal from the GPIO to the interface, wherein selecting the first chiplet from the plurality of chiplets includes utilizing the selection signal.

20. The method of claim 16 wherein the first main die includes a main die AXI network and the first chiplet includes a first chiplet AXI network, and wherein the cross-die AXI network and the main die AXI network form an extended main die AXI network.
